(19) United States
(12) Patent Application Publication
(10) Pub. No.: US 2011/0292611 A1
(43) Pub. Date: Dec. 1, 2011

(54) SEMICONDUCTOR-DEVICE COOLING STRUCTURE AND POWER CONVERTER

(75) Inventors: Masato HIGUCHI, Fukuoka (JP); Yasuhiko Kawanami, Fukuoka (JP); Akira Sasaki, Fukuoka (JP)

(73) Assignee: KABUSHIKI KAISHA YASKAWA DENKI, Kitakyushu-shi (JP)

(21) Appl. No.: 13/206,487

(22) Filed: Aug. 9, 2011

Related U.S. Application Data
(63) Continuation of application No. PCT/JP2010/051852, filed on Feb. 9, 2010.

(30) Foreign Application Priority Data
Feb. 9, 2009 (JP) 2009-027175
Jun. 19, 2009 (JP) 2009-146955

(51) Int. Cl. H05K 7/20

(52) U.S. Cl. 361/717

(57) ABSTRACT

A power converter includes a plurality of semiconductor modules each including a semiconductor device that generates heat and a cooler that includes a first cooling element, on which the semiconductor device is directly mounted through a connecting member, and a second cooling element having a higher heat capacity than the first cooling element, and an insulating casing receiving the semiconductor modules to electrically isolate the semiconductor devices from each other.

### CROSS REFERENCE TO RELATED APPLICATIONS

The present application is continuation application of PCT/JP2010/051852, filed Feb. 9, 2010, which claims priority to Japanese Patent Application Nos. 2009-027175, filed Feb. 9, 2009 and 2009-146955, filed Jun. 19, 2009. The contents of these applications are incorporated herein by reference in their entirety.

### BACKGROUND OF THE INVENTION

1. Field of the Invention

The present invention relates to a semiconductor-device cooling structure and a power converter.

2. Discussion of the Background

An input-output circuit of, for example, an inverter, a servo amplifier, or a switching power supply includes a plurality of power semiconductor elements, a driving circuit that drives the power semiconductor elements, and a control power supply circuit for the driving circuit. Since the power semiconductor elements and semiconductor elements included in the power supply circuit generate heat, the heat is dissipated through a cooling element, such as a heat sink. An example of the heat sink is disclosed in Japanese Unexamined Patent Application Publication No. 2003-259658.

### SUMMARY OF THE INVENTION

According to one aspect of the present invention, a semiconductor-device cooling structure includes a semiconductor device that generates heat, and a cooler that includes a first cooling element on which the semiconductor device is directly mounted through a connecting member and a second cooling element, the first cooling element having a first heat capacity, the second cooling element having a second heat capacity higher than the first heat capacity.

According to another aspect of the present invention, a power converter includes a plurality of semiconductor modules each including a semiconductor device that generates heat and a cooler that includes a first cooling element on which the semiconductor device is directly mounted through a connecting layer and a second cooling element having a higher heat capacity than the first cooling element, and an insulating casing that receives the semiconductor modules to electrically isolate the semiconductor modules from each other.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a perspective view of a power converter according to an embodiment of the present invention;

FIG. 2 is an exploded view of the power converter according to the embodiment;

FIG. 3 illustrates a semiconductor module having a cooling structure prior to engagement;

FIG. 4 illustrates the semiconductor module having the cooling structure after engagement;

FIG. 5 illustrates a semiconductor module having a cooling structure;

FIG. 6 illustrates a cooling structure covered with an insulating film;

FIG. 7 illustrates a power converter according to a modification of the embodiment;

FIG. 8 illustrates a power converter according to another modification;

FIG. 9 illustrates a power converter according to another modification;

FIG. 10 illustrates a power converter according to another modification;

FIG. 11 illustrates a power converter according to another modification;

FIG. 12 illustrates a power converter according to another modification;

FIG. 13 illustrates a power converter according to another modification; and

FIG. 14 illustrates the power converter according to the modification of FIG. 13.

### DESCRIPTION OF THE EMBODIMENTS

Embodiments will now be described with reference to the accompanying drawings, wherein like reference numerals designate corresponding or identical elements throughout the various drawings.

An embodiment relates to an exemplary application of the present invention to a dissipating structure for a semiconductor device used in a power converter. The semiconductor device includes a power semiconductor element that generates heat. Accordingly, the semiconductor device is provided with a cooler configured to dissipate the heat to the outside. This cooler is called a heat sink in some cases. Since the semiconductor device is made by a known semiconductor process, detailed explanation of the semiconductor device is omitted. The present embodiment and the drawings illustrate a plastic-molding package type semiconductor device sealed in plastic. The present embodiment can also be applied to a power semiconductor element (so-called bare chip) which is not sealed in plastic with reference to the description of this specification and the drawings.

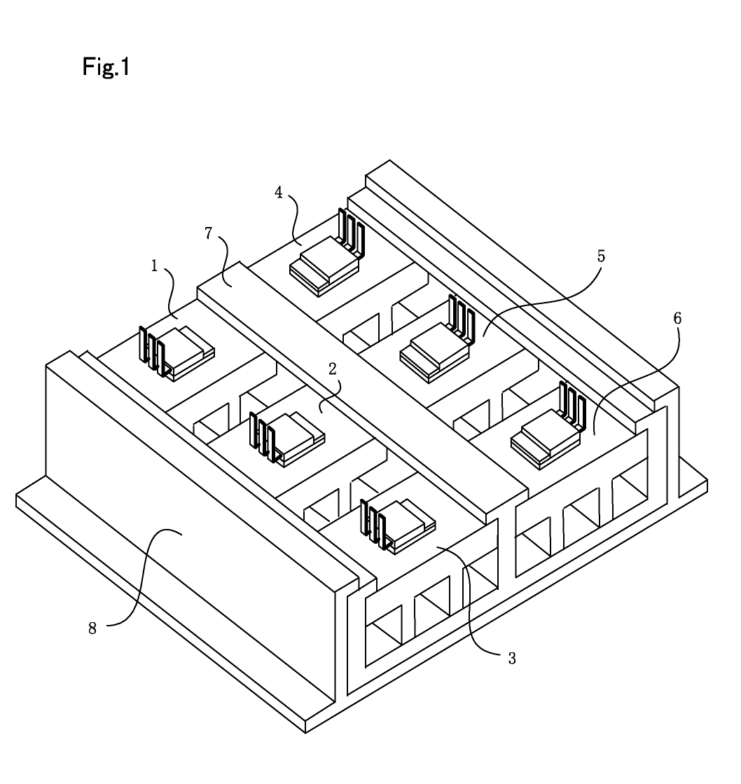

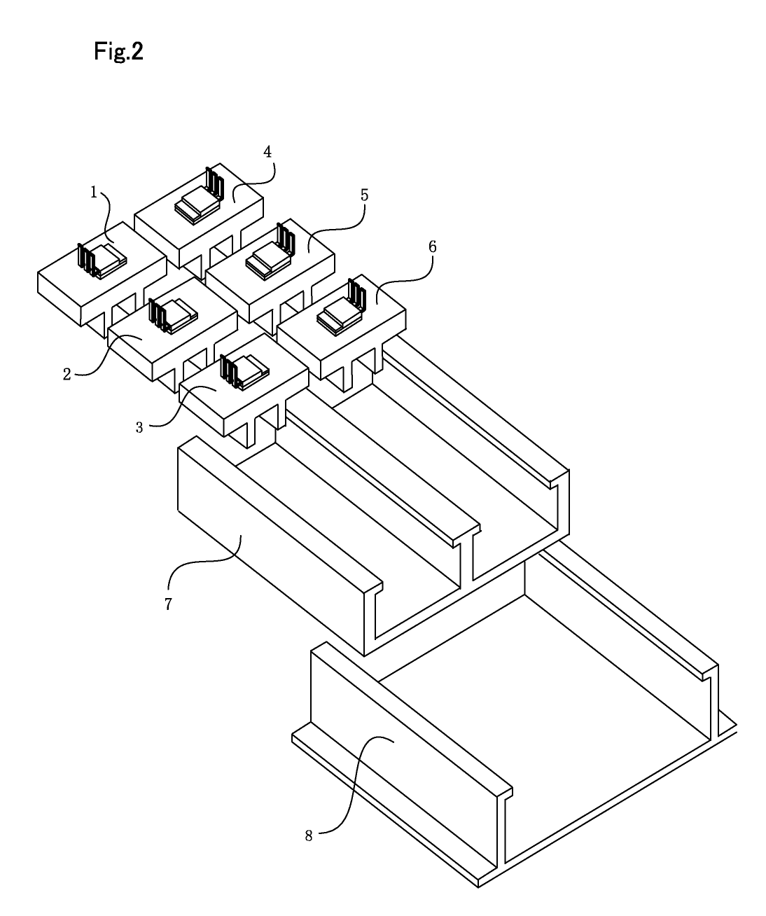

FIG. 1 illustrates a power converter including a plurality of semiconductor modules each having the above-described cooling structure that includes a semiconductor device, made by covering a power semiconductor element with a plastic molding package, and a cooling element to which the semiconductor device is joined. This power converter includes the semiconductor modules, indicated at 1 to 6. The semiconductor modules 1 to 6 are received in an insulating casing 7, so that the semiconductor modules are electrically isolated from one another. The insulating casing 7 is further received in a housing 8, thus increasing the mechanical strength of the power converter. FIG. 2 illustrates the semiconductor modules in FIG. 1 prior to being received in the insulating casing 7 and the housing 8.

Electrodes of the semiconductor modules 1 to 6 are joined to the cooling elements through a connecting member which is free of insulating material. Accordingly, each cooling element has the same potential as that of the electrode of the corresponding semiconductor module. If the cooling elements have different potentials, the insulating casing 7 is useful. The use of the insulating casing 7 ensures the isolation between each semiconductor module and the housing 8, serving as an outer frame. The insulating casing 7 can be a molding made of plastic. When the insulating casing 7 is received in the housing 8, the mechanical strength of the power converter can be increased. The housing 8 can be made of metal.

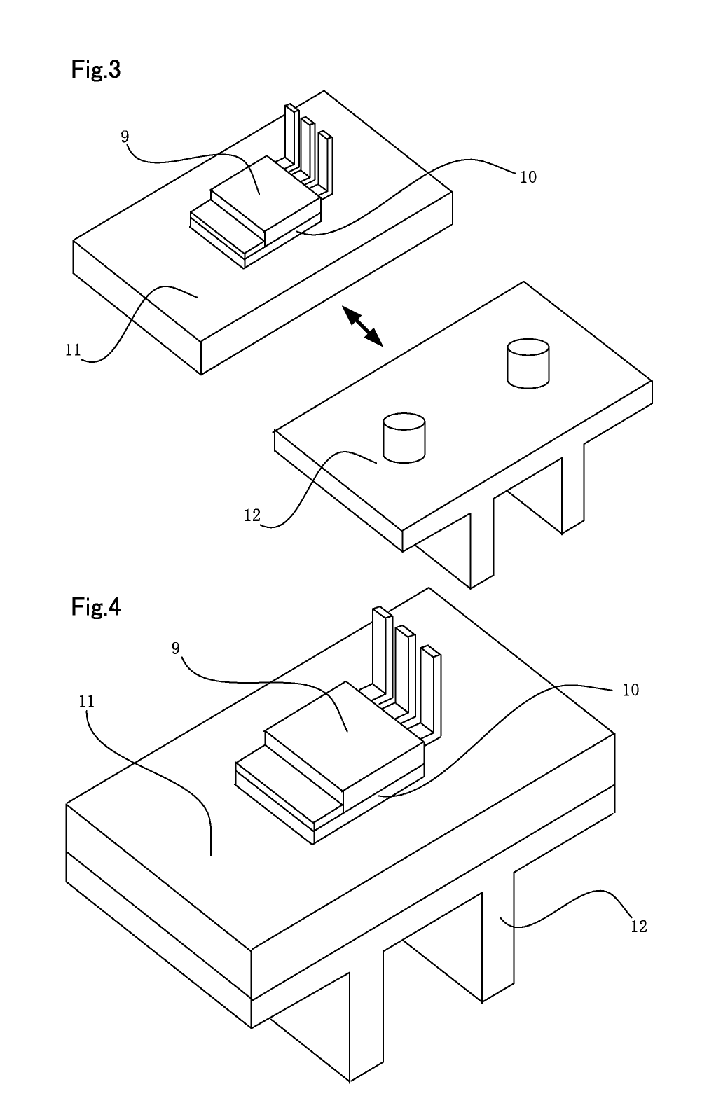

Referring to FIG. 3, a semiconductor device 9 is directly joined to a first cooling element 11 through a connecting member 10. On the rear surface of the semiconductor device 9, electrodes electrically connected to an internal circuit included in the semiconductor device 9 are exposed. The electrodes are directly joined to the first cooling element 11 with solder 10, serving as the connecting member 10. The first cooling element 11 has a low heat capacity so that the solder 10 can be joined to the first cooling element 11. Consequently, the join between the first cooling element 11 and the solder 10 can be easily made. Since an insulating material is not interposed between the electrodes of the semiconductor device 9 and the first cooling element 11, the thermal resistance therebetween can be reduced.

A second cooling element 12 has a heat capacity higher than that of the first cooling element 11 and includes radiating fins. The first cooling element 11 is integrated with the second cooling element 12 into a cooling structure as illustrated in FIG. 4. The surfaces of the first and second cooling elements 11 and 12 to be integrated with each other are provided with engaging members, respectively. Referring to FIG. 3, the first cooling element 11 has engaging recesses and the second cooling element 12 has engaging protrusions, thus constituting the power semiconductor cooling structure in which the first and second cooling elements can be aligned with each other.

If the contact surfaces of the first and second cooling elements 11 and 12 each have a low surface roughness, a heat conductive material may be disposed between the first and second cooling elements 11 and 12. Thus, the thermal resistance between the contact surfaces can be further reduced.

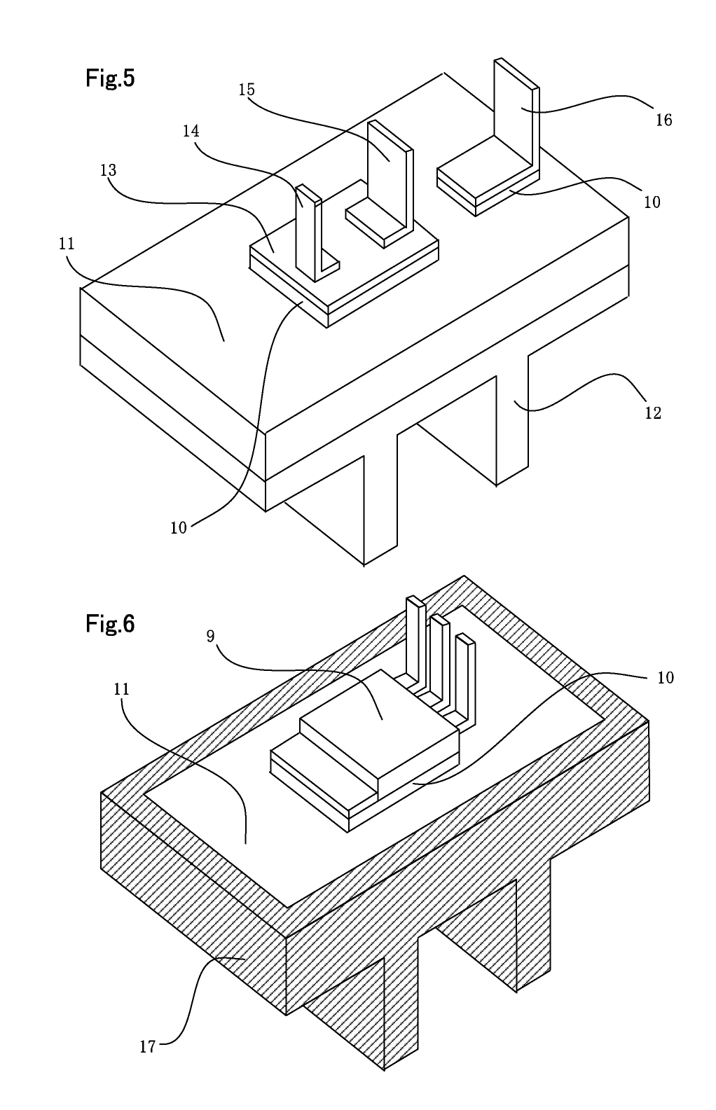

FIG. 5 illustrates a power semiconductor element 13 directly joined to the first cooling element 11. In this configuration, the power semiconductor element 13 is joined to the first cooling element 11 with the connecting member 10, the gate electrode of the power semiconductor module 13 is joined to a metal terminal 14, the source electrode thereof is joined to a metal terminal 15, and the drain electrode thereof is joined to a metal terminal 16 so that the power semiconductor element is connected to a higher-level network of the power converter. The cooling structure in FIG. 4 can be applied to any device if the device is not a semiconductor device, so long as the device has such a configuration.

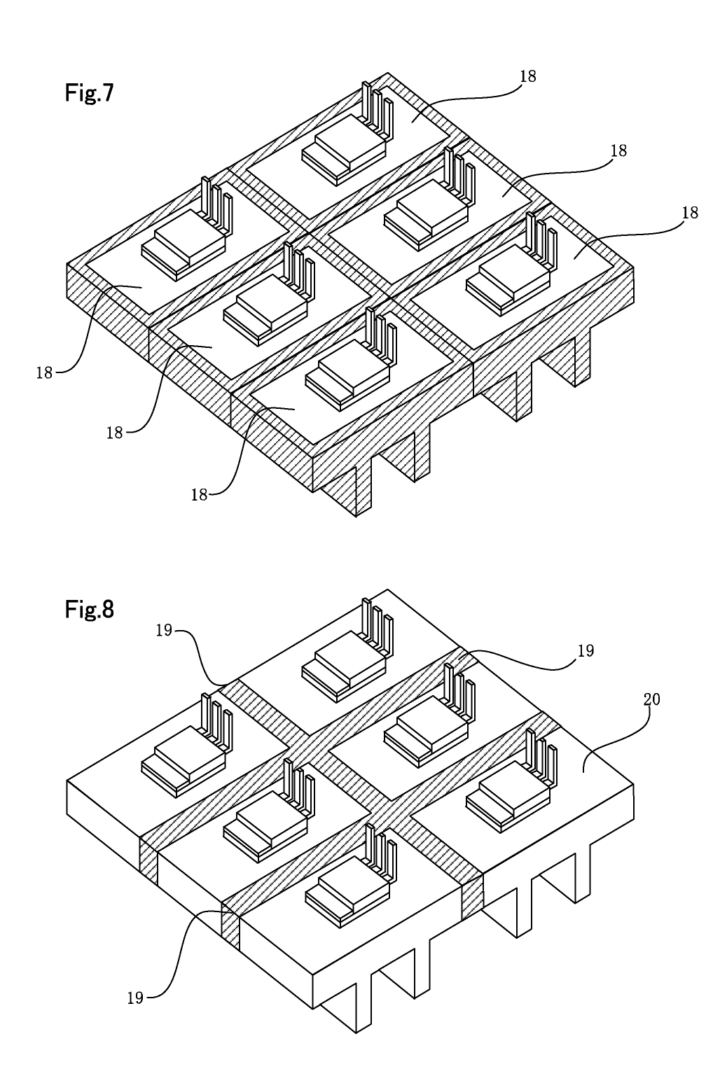

FIG. 6 illustrates the cooling structure in FIG. 4 covered with an electrically insulating film 17. When such a configuration is applied to a power converter including a plurality of semiconductor modules 18 as illustrated in FIG. 7, the semiconductor modules can be arranged close to one another without being apart from one another at an isolation distance. Thus, such a small power converter can be realized.

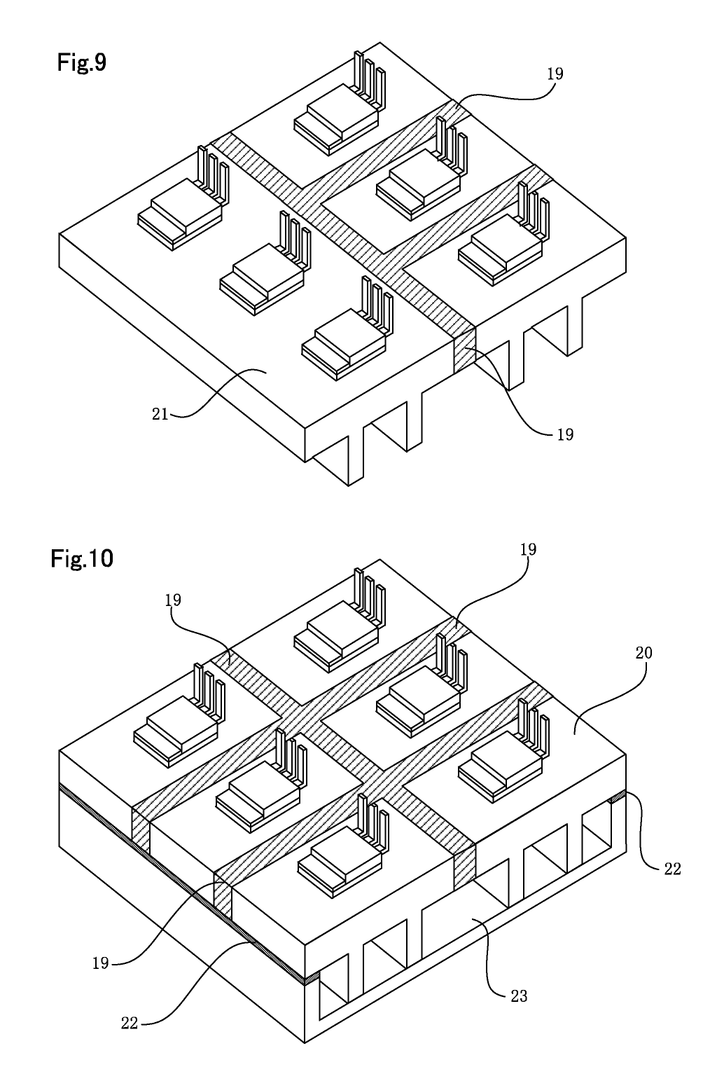

FIG. 8 illustrates a power converter according to another modification in which a cooling structure 20 includes cooling elements combined with one another and an insulating layer 19 such that the insulating layer 19 is disposed between the adjacent cooling elements. When semiconductor devices are joined to the upper surface of the cooling structure 20, semiconductor modules can be arranged close to one another. Thus, the small power converter can be realized. When the electrodes of some of the semiconductor devices joined to the cooling structure 20 have the same potential, the semiconductor devices having the electrodes at the same potential can be joined to the same cooling element without the insulating layer therebetween, as in a cooling structure 21 illustrated in FIG. 9. In this case, a smaller cooling structure reduced in size by the amount of insulating layer reduced can be realized.

FIG. 10 illustrates a power converter according to another modification in which the cooling structure 20 of FIG. 8 is combined with a recessed liquid cooling structure 23 with a sealing member 22 therebetween. A liquid cooling medium can flow in the liquid cooling structure 23. According to this modification, the liquid cooling structure having high cooling efficiency can be realized.

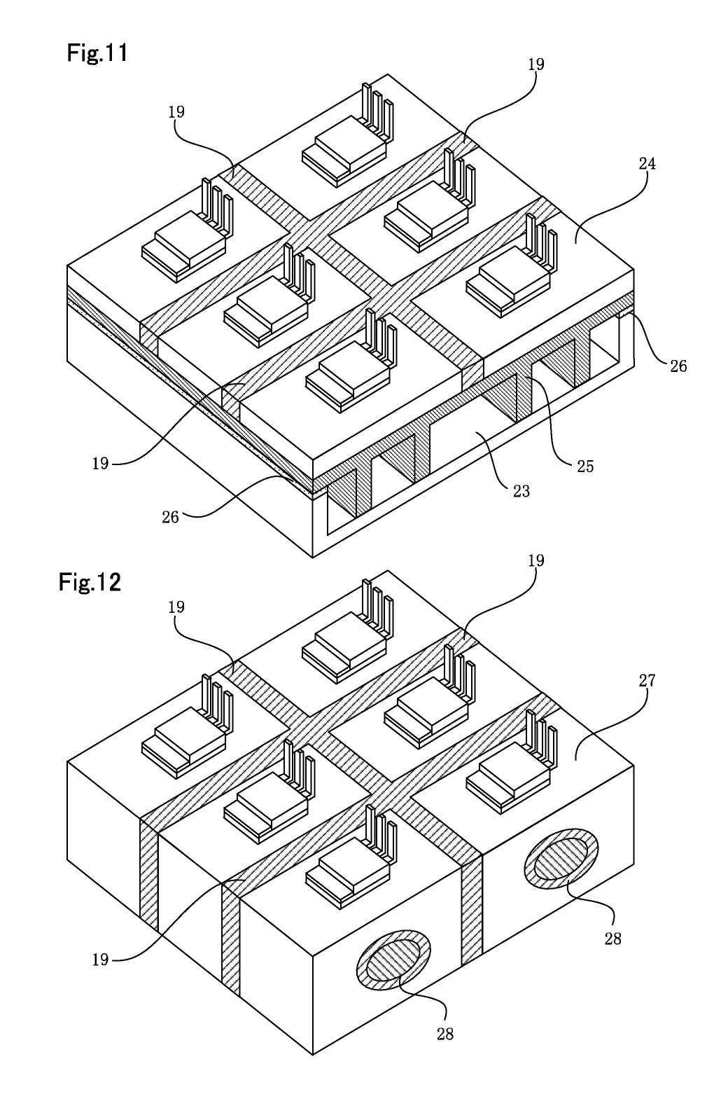

Since the liquid cooling medium is in direct contact with the cooling structure 20 in FIG. 10, the cooling medium has to be made of an electrically insulating material. When a cooling structure 24 including fins covered with an insulating film 25, as illustrated in FIG. 11, is combined with the recessed liquid cooling structure 23 with a sealing member 26 therebetween, a non-insulating cooling medium can be used.

According to another modification, as illustrated in FIG. 12, a power converter may include a cooling structure 27 having liquid cooling holes 28, which a cooling medium can pass through, instead of the fins of the cooling structure 24 of FIG. 11. Each liquid cooling hole 28 extends through the cooling structure 27. The insulating layer 19 has through-holes which the liquid cooling holes 28 extend through. According to this modification, a configuration simpler than that in FIG. 11 can be obtained. Thus, a low-profile cooling structure can be realized. When the inner surface of each liquid cooling hole is covered with an insulating film, a non-insulating cooling medium can be used.

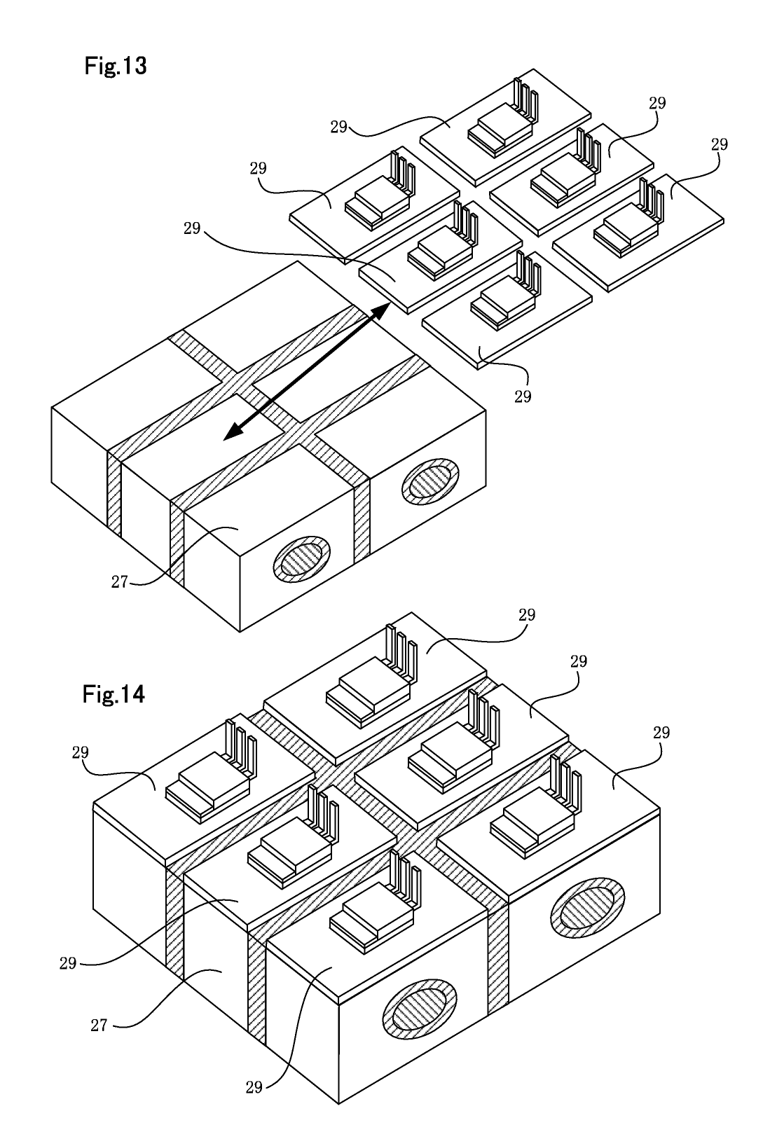

FIGS. 13 and 14 illustrate a power converter according to another modification. A metal plate 29 is disposed between each semiconductor device and the cooling structure 27. According to this modification, it is unnecessary to join the semiconductor devices to the cooling structure having a high heat capacity. Each semiconductor device is simply joined to the metal plate, so that the semiconductor device can be indirectly joined to the cooling structure. Thus, the power converter can be easily made.

In the above-described embodiment, the semiconductor devices comprising silicon are used. When the present invention is applied to a SiC or GaN semiconductor device that generates a high temperature heat at or above 400° C., preferred advantages are obtained.

The present invention can be applied to a servo drive used in, for example, a machine tool, a robot, or a general industrial machine, an inverter, and a general switching power supply.

Obviously, numerous modifications and variations of the present invention are possible in light of the above teachings. It is therefore to be understood that within the scope of the appended claims, the invention may be practiced otherwise than as specifically described herein.

What is claimed as new and is desired to be secured by Letters Patent of the United States is:

1. A semiconductor-device cooling structure comprising:
a semiconductor device that generates heat; and
a cooler that includes a first cooling element on which the semiconductor device is directly mounted through a connecting member and a second cooling element, the first cooling element having a first heat capacity, the second cooling element having a second heat capacity higher than the first heat capacity.

2. The structure according to claim 1, wherein an electrode electrically connected to an internal circuit included in the semiconductor device is exposed on the principal surface of the semiconductor device and the electrode is joined to the first cooling element with the connecting member.

3. The structure according to claim 2, wherein the connecting member is free of insulating material.

4. The structure according to claim 1, wherein the first cooling element is integrated with the second cooling element through a first engaging member included in the first cooling element and a second engaging member included in the second cooling element.

5. The structure according to claim 4, wherein the second engaging member is a protrusion protruding from the second cooling element and the first engaging member is a recess receiving the protrusion.

6. The structure according to claim 4, wherein a heat conductive member is disposed between the first and second cooling elements.

7. The structure according to claim 6, wherein the surfaces of the integrated first and second cooling elements are covered with an electrically insulating film.

8. A power converter comprising:
a plurality of semiconductor modules each including a semiconductor device that generates heat and a cooler that includes a first cooling element, on which the semiconductor device is directly mounted through a connecting layer, and a second cooling element having a higher heat capacity than the first cooling element; and
an insulating casing that receives the semiconductor modules to electrically isolate the semiconductor modules from each other.

9. The power converter according to claim 8, further comprising:
a housing that receives the insulating casing.

10. A power converter comprising:
a plurality of cooling elements;
a plurality of semiconductor devices each of which is mounted on the corresponding cooling element through a connecting layer; and
an insulating layer disposed between the adjacent cooling elements.

11. The power converter according to claim 10, wherein each cooling element has a liquid cooling hole to which a cooling medium is supplied.

12. The power converter according to claim 11, further comprising:
a metal layer disposed between each cooling element and the corresponding semiconductor device.
